(19) United States
(12) Patent Application Publication
(10) Pub. No.: US 2024/0399719 A1
(43) Pub. Date: Dec. 5, 2024

(54) FUNCTIONAL GLASS AND ARTIFICIAL GLASS LAMINATES

(71) Applicant: DelStar Technologies, Inc., Alpharetta, GA (US)

(72) Inventors: James Kidwell, Maple Grove, MN (US); Tom Niziolek, Middletown, DE (US)

(21) Appl. No.: 18/679,936

(22) Filed: May 31, 2024

Related U.S. Application Data
(60) Provisional application No. 63/470,128, filed on May 31, 2023.

(51) Int. Cl. B32B 17/10; B82Y 20/00; E06B 9/24; G02F 1/133; G02F 1/1343; G02F 1/155; G02F 1/163; H02S 20/26; H10K 30/35; H10K 30/50; H10K 30/87

(52) U.S. Cl. CPC B32B 17/10513; B32B 17/10036; B32B 17/10743; B32B 17/10752; B32B 17/10761; B32B 17/1077; B32B 17/10779; B32B 17/10788; E06B 9/24; G02F 1/13324; G02F 1/13439; G02F 1/155; G02F 1/163; H02S 20/26; H10K 30/35; H10K 30/50; H10K 30/87; B32B 2274/00; B32B 2419/00; B32B 2605/00; B82Y 20/00; E06B 2009/2464; E06B 2009/2476; G02F 2202/36

(57) ABSTRACT

A functional glass, an artificial glass laminate, and a self-contained window unit formed therefrom can include functional performance layers such as an electrochromic assembly in one layer, and a photovoltaic assembly in another layer. The photovoltaic assembly may include a polymeric interlayer having transparent photovoltaic cells disposed therein, or a thin film of organic photovoltaic cells, the photovoltaic cells providing electrical power to the electrochromic assembly. A first layer of glass and a second layer of glass separated by a gap may be disposed between the electrochromic assembly and the polymeric interlayer. The glass, laminate and window unit are optically clear.

### CROSS-REFERENCE TO RELATED APPLICATIONS

This application claims the benefit of United States Provisional No. 63/470,128 filed May 31, 2023, the complete disclosure of which is incorporated herein by reference for all purposes.

### TECHNICAL FIELD

This relates to glass and artificial glass laminates having photovoltaic, electrochromic and/or other functionalities for conductive performance.

### BACKGROUND

Functional glass and artificial glass laminates are used in windows for buildings and vehicles. Photovoltaic features have been used in such windows to harness energy from sunlight. Although a variety of photovoltaic technologies exist, it has not been possible to incorporate solar power generating technology into a window that has good optical and aesthetic characteristics. Furthermore, windows can generate undesirable heat gain for a building or vehicle, requiring air conditioning and reducing the energy efficiency.

Electrochromic technology changes the light transmissivity of a window on the application of an electric current through an ion conducting material. This can control the heat gain through the window from sunlight. However, ion conducting materials that will not leak from the window and have the desired optical characteristics have not been developed. Also, electrochromic windows are not self-contained, and require electrical connections to the building or vehicle.

Another challenge in developing glass and artificial glass laminates for windows is that the photovoltaic features generate heat that can interfere with the ion conducting material and further add to heat gain and reductions in energy efficiency.

### SUMMARY

The following presents a simplified summary of the claimed subject matter in order to provide a basic understanding of some aspects of the claimed subject matter. This summary is not an extensive overview of the claimed subject matter. It is intended to neither identify key or critical elements of the claimed subject matter nor delineate the scope of the claimed subject matter. Its sole purpose is to present some concepts of the claimed subject matter in a simplified form as a prelude to the more detailed description that is presented later.

A laminate having transparent electrochromic technology incorporating an ion conducting interlayer film and conductive films as electrodes can be powered by a transparent photovoltaic interlayer requiring no external power. The laminate can be incorporated in a self-contained window unit, without requiring wiring connections outside of the unit, improving the energy efficiency of a building or vehicle. In exemplary embodiments, the ion conducting interlayer film and conductive electrodes are transparent, or substantially transparent, and have the light transmissivity and aesthetic characteristics desirable for windows, windshields, and sunroofs. The photovoltaic interlayer may be a polymeric interlayer, in some embodiments, that can be extruded and laminated and can have photovoltaic cells that are transparent. In certain embodiments, the photovoltaic cells are quantum dots. In other embodiments, organic photovoltaic cells are employed for the photovoltaic assembly. These organic photovoltaic cells may be provided as a thin film.

According to one exemplary aspect, a functional laminate comprises an electrochromic assembly having an ion conducting interlayer film, a first electrode layer, and a second electrode layer, the first electrode layer and the second electrode layer being configured to apply an electric potential across the ion conducting interlayer film. A first layer of glass and a second layer of glass is provided with a gap therebetween. A photovoltaic assembly is also provided, the photovoltaic assembly being electrically connected to the electrochromic assembly. The first layer of glass and second layer of glass can be disposed between the electrochromic assembly and the photovoltaic assembly.

The functional laminate can be optically clear. In some embodiments, the functional laminate allows a light transmission of about 85% to about 93%. The functional laminate may also have a haze of about 5% to less than about 1%.

In some embodiments, the first electrode layer and the second electrode layer are conductive films including carbon nanotubes. The photovoltaic assembly may include luminescent solar concentrators, such as quantum dots. The photovoltaic assembly may also include organic photovoltaic cells in another embodiment. These organic photovoltaic cells may be contained in a thin film.

The photovoltaic assembly may include a polymeric interlayer, with the luminescent solar concentrators being disposed in the polymeric interlayer. The polymeric interlayer can comprise ethylene co-vinyl acetate (EVA) or thermoplastic polyurethane (TPU).

In some embodiments, the first electrode layer and the second electrode layer are transparent. In certain embodiments, at least one of the first electrode layer and the second electrode layer have carbon nanotubes and another element selected from the group of materials that include carbon, graphite, silver, and copper.

In exemplary embodiments, the ion conducting interlayer film is transparent. The ion conducting interlayer film can include a material comprising thermoplastic polyurethane (TPU) or polymethyl methacrylate (PMMA). In some embodiments, the ion conducting interlayer film includes an organic carbonate. In certain embodiments, the ion conducting interlayer film includes a dibenzoate or an acrylic monomer.

In exemplary embodiments, the gap between the first layer of glass and the second layer of glass is a vacuum. In certain embodiments, the gap between the first layer of glass and the second layer of glass contains a noble gas.

In another exemplary aspect, a self-contained window unit is providing having a functional laminate comprising an electrochromic assembly having an ion conducting interlayer film, a first electrode layer, and a second electrode layer, the first electrode layer and the second electrode layer being disposed to direct an electric current across the ion conducting interlayer film. A first layer of glass and a second layer of glass is provided and has a gap therebetween. A photovoltaic assembly electrically connected to the electrochromic assembly is provided. The first layer of glass and second layer of glass is disposed between the electrochromic assembly and the photovoltaic assembly.

The unit can further comprise a frame. The unit can further comprise a transceiver. The operation of the electrochromic assembly, in embodiments, is automatically controlled. In some embodiments, the unit is connected to at least one of a wireless controller, mini blinds, an IoT device, and a sensor management operating system.

In certain embodiments, the electrochromic assembly includes a carrier comprising polyethylene terephthalate (PET) or polycarbonate (PC). The electrochromic assembly can be formed on the carrier. In some embodiments, the second electrode layer is formed directly on the carrier. An optical interlayer can be disposed on the carrier opposite the second electrode layer. The optical interlayer can be selected from a group consisting of a polyvinyl butyral (PVB) layer, a solar control layer, and an optical grade EVA.

In a further exemplary aspect, a functional laminate comprises a first layer of glass, a photovoltaic assembly disposed on the first layer of glass, a second layer of glass, a third layer of glass, and a gap therebetween the second and third layers of glass. An electrochromic assembly is disposed on the third layer of glass, the electrochromic assembly having an ion conducting interlayer film, a first electrode layer, and a second electrode layer. The first electrode layer and the second electrode layer are configured to apply an electric potential across the ion conducting interlayer film. The photovoltaic assembly is electrically connected to the electrochromic assembly. A fourth layer of glass is disposed on a side of the electrochromic assembly opposite the third layer of glass.

In certain embodiments, a fifth layer of glass is provided adjacent the fourth layer of glass, with a gap disposed between the fourth layer of glass and the fifth layer of glass. In some embodiments, a layer of TPU is disposed on the fifth layer of glass and a sixth layer of glass is disposed on the layer of TPU.

In some exemplary embodiments, the first electrode layer and the second electrode layer are conductive films including carbon nanotubes. In some embodiments, the photovoltaic assembly includes luminescent solar concentrators. These luminescent solar concentrators can comprise quantum dots. The photovoltaic assembly may also include organic photovoltaic cells in another embodiment. These organic photovoltaic cells may be contained in a thin film.

The photovoltaic assembly may include a polymeric interlayer, with the luminescent solar concentrators being disposed in the polymeric interlayer. The polymeric interlayer can comprise ethylene co-vinyl acetate (EVA) or thermoplastic polyurethane (TPU).

In some embodiments, the first electrode layer and the second electrode layer are transparent. For example, at least one of the first electrode layer and the second electrode layer have carbon nanotubes. In certain embodiments, at least one of the first electrode layer and the second electrode layer have another element selected from the group of materials that include carbon, graphite, silver, and copper.

In some embodiments, the ion conducting interlayer film is transparent. In certain embodiments, the ion conducting interlayer film includes a material such as thermoplastic polyurethane (TPU) or polymethyl methacrylate (PMMA). The ion conducting interlayer film can include an organic carbonate. The ion conducting interlayer film can include a dibenzoate or an acrylic monomer.

In exemplary embodiments, the gap between the second layer of glass and the third layer of glass is a vacuum. In certain embodiments, the gap between the second layer of glass and the third layer of glass contains a noble gas.

In still another exemplary aspect, a self-contained window unit having a functional laminate comprises a first layer of glass, a photovoltaic assembly disposed on the first layer of glass, a second layer of glass, a third layer of glass, and a gap therebetween. An electrochromic assembly is disposed on the third layer of glass, the electrochromic assembly having an ion conducting interlayer film, a first electrode layer, and a second electrode layer. The first electrode layer and the second electrode layer are disposed to direct an electric current across the ion conducting interlayer film. The photovoltaic assembly is electrically connected to the electrochromic assembly. A fourth layer of glass is disposed on a side of the electrochromic assembly opposite the third layer of glass.

The unit can further comprise a frame. The unit can further comprise a transceiver. The operation of the electrochromic assembly, in embodiments, is automatically controlled. In some embodiments, the unit is connected to at least one of a wireless controller, mini blinds, an IoT device, and a sensor management operating system.

In certain embodiments, the electrochromic assembly includes a carrier comprising polyethylene terephthalate (PET) or polycarbonate (PC). The electrochromic assembly can be formed on the carrier. In some embodiments, the second electrode layer is formed directly on the carrier. An optical interlayer can be disposed on the carrier opposite the second electrode layer. The optical interlayer can be selected from a group consisting of a PVB layer, a solar control layer, and an optical grade EVA.

### BRIEF DESCRIPTION OF THE DRAWINGS

The accompanying drawings, which are incorporated in and constitute a part of this specification, illustrate several embodiments of the disclosure and, together with the description, serve to explain the principles of the disclosure.

FIG. 1 is a schematic cross-sectional view of a multilayer laminate according to an exemplary embodiment.

FIG. 2 is a perspective view of a photovoltaic assembly in accordance with an exemplary embodiment.

FIG. 3 is a perspective view of an electrochromic assembly in accordance with an exemplary embodiment.

FIG. 4 is a partial, cross-sectional view of an insulated glass unit (“IGU”) according to an exemplary embodiment.

FIG. 5 is a perspective schematic view of a multilayer laminate according to an exemplary embodiment.

FIG. 6 is a perspective schematic view of a multilayer laminate according to a further exemplary embodiment.

### DETAILED DESCRIPTION

This description and the accompanying drawings illustrate exemplary embodiments and should not be taken as limiting, with the claims defining the scope of the present disclosure, including equivalents. Various mechanical, compositional, structural, and operational changes may be made without departing from the scope of this description and the claims, including equivalents. In some instances, well-known structures and techniques have not been shown or described in detail so as not to obscure the disclosure. Like numbers in two or more figures represent the same or similar elements. Furthermore, elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment. Moreover, the depictions herein are for illustrative purposes only and do not necessarily reflect the actual shape, size, or dimensions of the system or illustrated components.

It is noted that, as used in this specification and the appended claims, the singular forms “a,” “an,” and “the,” and any singular use of any word, include plural referents unless expressly and unequivocally limited to one referent. As used herein, the term “include” and its grammatical variants are intended to be non-limiting, such that recitation of items in a list is not to the exclusion of other like items that can be substituted or added to the listed items.

In exemplary embodiments, functional glass and artificial glass laminates can incorporate an electrochromic assembly and a photovoltaic assembly, with the photovoltaic assembly providing power to the electrochromic assembly, in a laminated material that includes a gap between the electrochromic assembly and the photovoltaic assembly. The gap protects the electrochromic assembly from the heat generated by the photovoltaic assembly and reduces the heat conducted to the interior side of the window. In some embodiments, additional layers can be added on the electrochromic assembly on the side opposite the photovoltaic assembly, to further insulate the interior of a building or car from any added heat generated where the laminate is used as a window, skylight, etc.

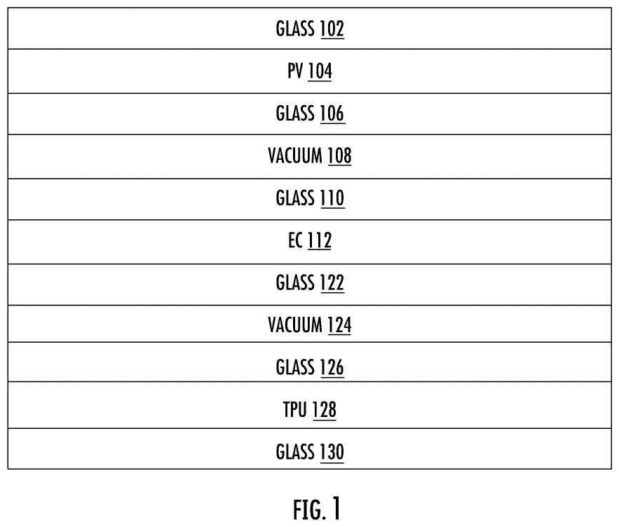

In certain embodiments, as represented in FIG. 1, the laminate has a first layer of glass 102 and a photovoltaic assembly (“PV”) 104 disposed on the first layer of glass. The photovoltaic assembly 104 has a transparent layer incorporating a plurality of luminescent solar concentrators (“LSC”), which may be, in some embodiments, colloidal semiconductor nanocrystals, also called quantum dots. The quantum dots are typically less than 20 nanometers in diameter and are not visible. Natural light excites electrons of the quantum dot which guides the light to the sides of the layer. For example, the light is guided to the long sides of the layer. Photovoltaic cells in intimate contact with the side of the layer convert the light to electrical energy. In some embodiments, other luminescent solar concentrators are used.

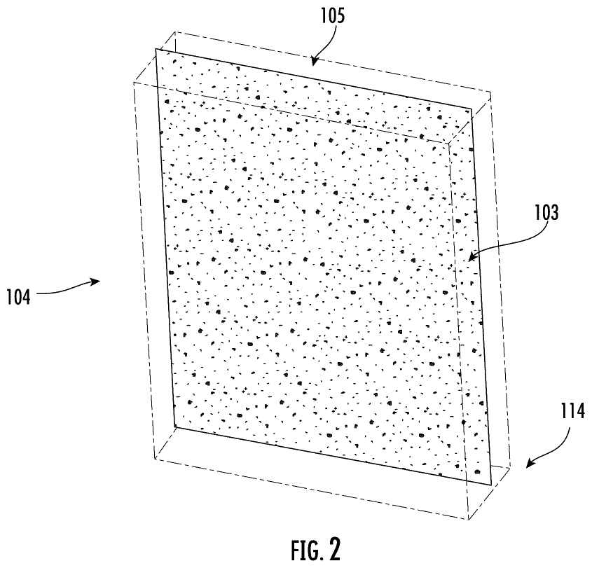

As shown in FIG. 2, the photovoltaic assembly 104 is provided as a polymeric layer 105 that can be extruded and laminated with other layers. For example, quantum dots 103 can be provided in a thermoplastic polyurethane (“TPU”), polymethyl methacrylate (“PMMA”), or ethylene co-vinyl acetate (“EVA”). The layer can be extruded by a single or two screw extrusion, cast, coated, UV cured, or formed by another suitable process. In some embodiments, layer 105 is an ionomer. While FIG. 2 shows the quantum dots 103 schematically as a texture for purposes of explanation of the concept, it is understood that the quantum dots are not visible.

Another suitable and alternative to quantum dots for energy generation is organic photovoltaic (OPV) cells, which may be employed here. Organic photovoltaic technology is rapidly emerging due to improving cell efficiency, positive performance lifetime, and demonstrated potential for roll-to-roll manufacturing using solution processing. OPV may be an attractive alternative since it offers absorbers in any color, and the ability to make efficient transparent devices. A diversity of organic materials can be used to design and synthesize the absorber, acceptor and interfaces, another benefit. Organic photovoltaic cells may be applied using thin-film deposition such as by sputtering and pulsed-laser deposition to create this thin-film OPV for energy generation.

Turning back to FIG. 1, a second layer of glass 106 is disposed on the photovoltaic assembly in some embodiments. A third layer of glass 110 is provided adjacent the second layer of glass 106, separated by a gap 108. This gap 108 in between the second layer of glass 106 and the third layer of glass 110 may comprise air or a vacuum. In other examples, a gas such as argon, krypton, or another noble gas is in the gap 108 in between the second layer of glass 106 and the third layer of glass 110.

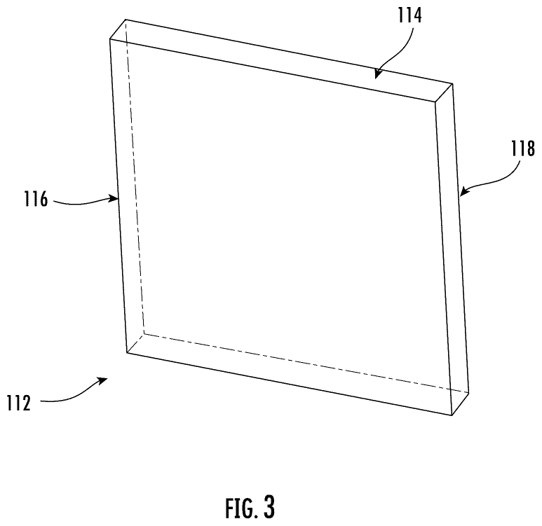

An electrochromic assembly (“EC”) 112 is disposed on the third layer of glass 110, in some embodiments. As shown in FIG. 3, the electrochromic assembly 112 includes an ion conducting interlayer film 114 disposed between a first electrode layer 116 and a second electrode layer 118. Wires can connect the photovoltaic assembly to the electrochromic assembly, in some embodiments, with the photovoltaic assembly providing power to the electrochromic assembly. In other examples, the electrical connection can be a busbar, conductive traces, or some other form of electrical connection. In certain embodiments, the electrochromic assembly 112 is connected to an electric potential that is external to the window unit.

The first transparent electrode layer 116 and the second transparent electrode layer 118 can be an electrically conductive layer such as, for example, a transparent conductive film (“TCF”) or transparent conductive coating. Transparent conductive films or coatings are used in a variety of electronic devices such as photovoltaics, touch screens and displays. One example is indium tin oxide (“ITO”). Others include transparent conductive oxides (“TCO”), conductive polymers, metal meshes, carbon nanotubes (“CNT”), graphene, nanowires, and ultra-thin metal films.

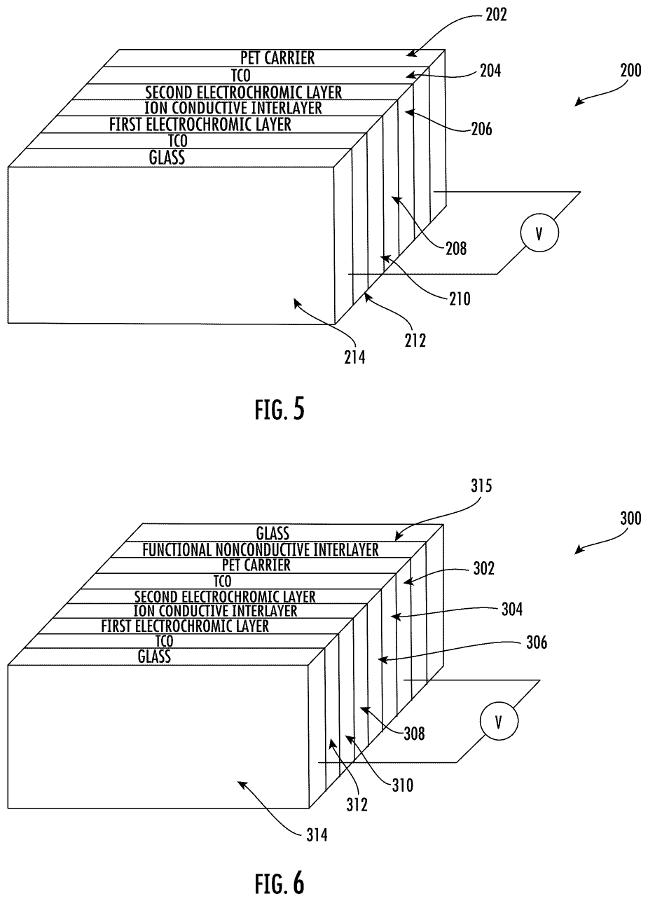

In some exemplary embodiments, the transparent conductive electrodes include a layer incorporating carbon nanotubes. In certain embodiments, the transparent conductive electrodes are made from nanotube hybrids, which combine carbon nanotubes with another element, such as carbon, graphite, silver, or copper. As represented in FIG. 5, the transparent conductive electrodes function as an anode and a cathode on the application of an electric potential.

The ion conducting interlayer film 114 is disposed between the first electrode layer 116 and the second electrode layer 118 (see FIG. 3). A lithium salt, in certain embodiments, is provided in a polymer layer such as a TPU, EVA, or PMMA layer. In some embodiments, the film 114 is extruded and laminated with other layers. This avoids using liquid electrolytes that can potentially leak. In certain embodiments, a polymer can be plasticized with the liquid electrolyte. For example, TPU can be plasticized with polypropylene carbonate containing a lithium salt. For better transparency, particular organic carbonates can be used as the plasticizer. In an example, an organic carbonate and a dibenzoate or acrylic monomer can be used as the plasticizer, with TPU or polymethyl methacrylate (“PMMA”) and a lithium salt. Further examples of polymerized ion conducting interlayer films are discussed below and can be used in the laminate shown in FIG. 1. In other embodiments, the ion conducting layer is cast, coated, UV cured, or formed using other methods.

A fourth layer of glass 122 is disposed on the electrochromic assembly 112, on a side opposite the third layer of glass 110, in certain exemplary embodiments as represented in FIG. 1. In certain embodiments, additional layers are added to further insulate the interior of a building or vehicle, where the laminate is used as part of a window. For example, a fifth layer of glass 126 is disposed adjacent the fourth layer of glass 122, with a gap 124 disposed therebetween. In certain embodiments, and similar to gap 108 discussed above, the gap 124 can comprise air or a vacuum. In other embodiments, the gap contains argon, krypton, or another noble gas. In some embodiments, a layer of TPU 128 is disposed on the fifth layer of glass 126. In certain embodiments, a sixth layer of glass 130 is disposed on the TPU 128. The TPU 128 and glass 130 provide further insulation from heat on the interior side of the window.

It is understood that additional layers can be added for impact and/or ballistic resistance, penetration resistance and/or structural strength, for example, as discussed below, such as polyvinyl butyral (“PVB”), etc. In some embodiments, layers are added for electromagnetic shielding.

The laminates disclosed herein can be incorporated in a self-contained window unit. Incorporating an electrochromic assembly and a photovoltaic assembly, the window unit controls transmittance of light, and provides a source of electrical power for electrochromic features of the unit. The unit is self-contained without needing wiring connections to power sources outside the unit. Automatic control of light transmittance and other features can be included, while the unit has the optical characteristics and aesthetics required for windows.

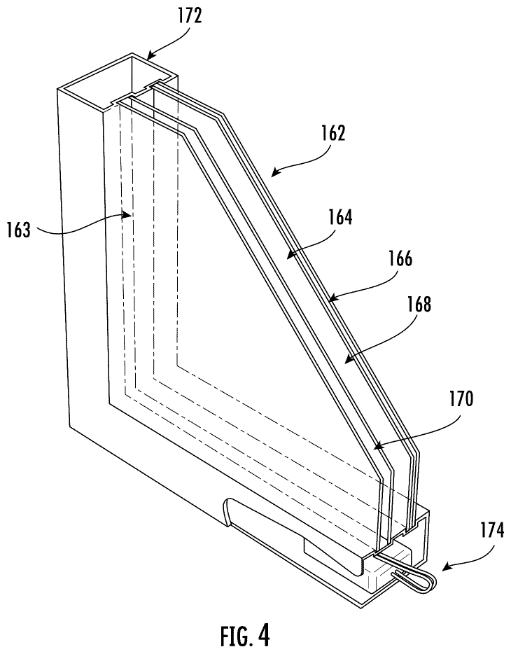

An insulated glass unit (“IGU”) according to an exemplary embodiment is shown in FIG. 4. The all-in-one dynamic glazing product comprises an IGU that has an electrochromic assembly 162 and a photovoltaic assembly 170 separated by a gap 168 and held together in a frame 172. The electrochromic assembly 162 includes a first electrode layer 163, a second electrode layer 164, and an ion conducting interlayer film 166 disposed between the first electrode layer 103 and the second electrode layer 104. The application of an electrical potential across the assembly results in a change in color and the light transmissivity of the assembly. The electrochromic assembly can vary the degree of light transmissivity to a desired extent. This can reduce the need for cooling in a building or vehicle, while allowing some light to enter. However, a source of electrical power is required to change the state of the electrochromic assembly.

The photovoltaic assembly 170 has a series of LSCs disposed in a polymeric interlayer that can be extruded and assembled into a laminate. For example, quantum dots can be provided in a thermoplastic polyurethane (“TPU”), ethylene co-vinyl acetate (“EVA”), or polymethyl methacrylate (“PMMA”). In some embodiments, the layer is extruded by a single or two screw extrusion, coated, cast, UV cured, or formed by other methods. Wires 174 connect the photovoltaic assembly to the electrochromic assembly, so that the IGU is a self-contained unit, with the photovoltaic assembly providing power to the electrochromic assembly. In other embodiments, the power for the electrochromic assembly is provided by an external source. The IGU may include a transceiver for wireless communication with an external control unit or computer for controlling the electrochromic aspects of the IGU automatically. For example, the electrochromic features can be used to block transmissivity of light during different hours of the day, and according to regimens that vary seasonally or based on user preferences. The IGU can communicate with home control systems through the transceiver and be part of a system that controls heating, ventilation and cooling, such as smart thermostats and other known systems, such as Internet of Things (IoT) devices. Similar systems and devices can be incorporated in a vehicle as well.

In some embodiments, the LSCs are colloidal semiconductor nanocrystals, also called quantum dots, which are typically less than 20 nanometers in diameter. Natural light excites electrons of the quantum dot and the energy is directed to the sides of the layer. Photovoltaic cells 103 convert the energy into electrical energy. For example, the photovoltaic cells are provided at the long sides of the layer, in intimate contact with it, or the photovoltaic cells are provided in areas adjacent to the transparent part of the window.

As understood and described above, a suitable alternative to the quantum dots for energy generation is organic photovoltaic (OPV) cells, which may also be employed here. Organic photovoltaic technology can offer improved cell efficiency, positive performance lifetime, and the potential for roll-to-roll manufacturing using solution processing. OPV may be an attractive alternative to the quantum dots since it offers absorbers in any color, and the ability to make efficient transparent devices. Additionally, the diversity of organic materials that can be used to design and synthesize the absorber, acceptor and interfaces, provides another benefit. Organic photovoltaic cells may be applied using thin-film deposition such as by sputtering and pulsed-laser deposition to create this thin-film OPV for energy generation.

The electrochromic assembly includes a first electrode layer and a second electrode layer that are transparent. Transparent conductive films (“TCF”) or coatings are used in a variety of electronic devices such as photovoltaics, touch screens and displays. One example is indium tin oxide (“ITO”). Others include transparent conductive oxides (“TCO”), conductive polymers, metal meshes, carbon nanotubes (“CNT”), graphene, nanowires, and ultra-thin metal films. ITO is very commonly used in electronic devices.

In some embodiments, the transparent electrodes include carbon nanotubes. In other embodiments, the transparent electrodes incorporate nanotube hybrids, which combine carbon nanotubes with another element, such as carbon, graphite, silver, or copper.

The ion conducting interlayer film is disposed between the first electrode layer and the second electrode layer. A lithium salt is provided in a polymer layer, in embodiments, that can be extruded and laminated with other layers. This avoids using liquid electrolytes that can potentially leak. A polymer can be plasticized with the liquid electrolyte. For example, TPU can be plasticized with polypropylene carbonate containing a lithium salt. For better transparency, particular organic carbonates can be used as the plasticizer. In an example, an organic carbonate and a dibenzoate or acrylic monomer was used as the plasticizer, with TPU or polymethyl methacrylate (“PMMA”) and a lithium salt. Further examples of a polymerized ion conducting interlayer are discussed below and can be used in a self-contained window unit, in embodiments.

In exemplary embodiments, a window unit includes a transmitter or transponder for communicating with a computer, microcontroller, or other device that controls the electrochromic features. In some embodiments, the window unit is connected to a smart thermostat or similar device. In certain embodiments, the window unit can include mechanically operated blinds powered by a photovoltaic assembly.

In exemplary embodiments, an electrochromic assembly is formed on a carrier film. In certain embodiments, the second electrode layer of an electrochromic assembly is formed on a carrier film. For example, as shown in FIG. 5, the second electrode layer is formed on a polyethylene terephthalate (“PET”) film 202. A TCO layer 204 and the second electrode layer 206 may be deposited on the PET film 202 instead of a glass pane. The second electrode layer can be as discussed herein, having carbon nanotubes, etc. The ion conducting layer 208, which may be made as discussed above, is formed on the coated PET carrier 202. The resulting laminate 200 form an electrochromic assembly as shown in FIG. 5, including first electrode layer 210, another TCO layer 212, and a layer of glass 214. The PET layer would not need to be removed from the electrolyte film prior to lamination but has one of the two electrodes in the electrochromic assembly, reducing steps, material usage, and improving operational efficiency. In some embodiments, polycarbonate (“PC”) may be used as the carrier instead of PET.

In certain embodiments, a second optical interlayer is added to the back of the PET carrier 302 to augment functional attributes of the laminated unit (see FIG. 6). The second optical interlayer 315 can comprise any one of the following:
a standard polyvinyl butyral (“PVB”) interlayer containing 38 phr triethylene glycol bis(2-ethylhexanoate) plasticizer;
an acoustic grade PVB interlayer (e.g., SAFLEX Q-Series® and SAFLEX E-Series® commercially available from Eastman of Kingsport, Tennessee, SEKISUI S-LEC® commercially available from Sekisui S-Lec America, LLC of Winchester, Kentucky, and acoustic-grade TROSIFOL® commercially available from Kuraray America, Inc. of Houston, Texas);
a solar control PVB, TPU or ionomeric interlayer to reduce heat gain;
a structural PVB interlayer containing 20 phr triethylene glycol bis(2-ethylhexanoate);
a structural ionomer (e.g., SentryGlas® Plus commercially available from Kuraray America, Inc. of Houston, Texas); and
an optical grade EVA interlayer.

In exemplary embodiments, the second functional nonconductive interlayer 315 itself may comprise several layers of non-plasticized TPU and polycarbonate layers to impart ballistic resistance.

In certain embodiments, the second functional nonconductive interlayer may be wedge shaped, and the glass pane next to it can represent the inboard side of a laminated glazing unit. The resulting laminate can be used in Head-Up Display (HUD) applications to eliminate ghosting of the projected image.

It is possible to reformulate the ion conductive interlayer by selecting other organic carbonates and cosolvents such that the Ra versus TPU is no more than 3.79. Examples of cosolvents may include, but are not limited to, other dibenzoate plasticizers such as 1, 4-Cyclohexane dimethanoldibenzoate (e.g., BENZOFLEX™ 352), benzoate esters (e.g., BENZOFLEX™ 2088 or BENZOFLEX™ 50) all of which are commercially available from Eastman of Kingsport, Tennessee, and the like, other phthalate plasticizers such as diisobutyl phthalate, diisononyl phthalate etc., other non-phthalate plasticizers such as 1,2-Cyclohexane dicarboxylic acid diisononyl ester (DINCH), and other non-aromatic plasticizers such as triethylene glycol bis(2-ethylhexanoate) (TEG-EH), tetraethylene glycol bis(2-ethylhexanoate), polyethelene glycol bis(2-ethylhexanoate) (PEG-EH), and the like.

Examples of organic carbonates include those listed in Table 1 below, other cyclic carbonates such as gamma-butyrolactone, and other linear carbonates such as dimethyl carbonate, methyl ethyl carbonate etc.

The mixed plasticizer may include one or more additives including, but not limited to, UV blockers, antioxidants, viscosity modifiers and alkali or alkaline earth metal salts. Of particular interest are Li salts such as LiCl, LiF, LiI, LiNO3, LiClO4, LiBF4, LiPF6, LiAsF6, lithium triflate, lithium imide, LiTFSI, LiTDI etc.

### EXAMPLES

### Example 1

Table 1 below provides the process conditions under which a polymer electrolyte film was extruded onto a carrier.

TABLE 1
Process Conditions used to Extrude Polymer Electrolyte Film on a Carrier.

| | | Motor | | | | | Winder | Winder | | |
|---|---|---|---|---|---|---|---|---|---|---|
| | AC Motor/ | Torque | Melt | Melt | Master | Rear Nip | 1 Speed/ | 2 Speed/ | | |
| Date/Time | Screw RPMs | Percent | Temp | Pressure | Speed | Trip | Torque | Torque | Width | Gauge (mils) |
| Process Conditions | 230/13 | 49 | 180 | 2700 | 1.3 | | | | | |
| Sample 1 | 230/13 | 46 | 237 | 50 | 1.1 | | | | | 15 mil |
| Extruder Temps | BZ 1 | BZ 2 | BZ 3 | BZ 4 | Adapter 1 | Adapter 2 | Die Zone 1 | Die Zone 2 | Die Zone 3 | Screen Changer |
| Starting Temps | 200 | 210 | 220 | 230 | 230 | 230 | 230 | 230 | 230 | 230 |
| Sample 1 | 255 | 275 | 285 | 285 | 285 | 285 | 285 | 285 | 285 | 285 |
| Better Temps | 260 | 280 | 290 | 300 | 290 | 290 | 290 | 290 | 290 | 290 |
| Roll Temps | Top | Mid | Bottom | Air Jets | Screens | | | | | |
| | 60 | 50 | 45 | OFF | Optical | | | | | |

When the interlayer was laminated between two glass electrodes, the resulting cell not only had low haze but also produced acceptable electrochromic performance.

It should be understood that the functional glasses, glass laminates, and the insulated glass units (IGUs) described herein can be incorporated into an all-in-one dynamic glazing product that is suitable for use as windows in buildings, dwellings, housing structures, transportation and construction equipment such as trucks, tractors and buses, automobiles, aviation devices such as airplanes and helicopters, protective storage containers such as glass sealed cases, optical lenses in electronic equipment, etc. and other such applications where glass or glass laminates with performance layers may be utilized. As such, these glasses, laminates and units should be optically clear so that the beneficial functionalities accorded them are not at the expense of the transparency of the material. By optically clear, what is meant is that the material may allow light transmission of at least about 85% and has a haze of less than about 5%. In some embodiments, the material preferably allows about 93% light transmission and has a haze of less than about 1%.

While the materials and products formed from these materials have been described in detail herein in accordance with certain preferred embodiments thereof, many modifications and changes therein may be effected by those skilled in the art. Accordingly, the foregoing description should not be construed to be limited thereby but should be construed to include such aforementioned obvious variations and be limited only by the spirit and scope of the following claims.

Other embodiments will be apparent to those skilled in the art from consideration of the specification and practice of the embodiment disclosed herein. It is intended that the specification and examples be considered as exemplary only, with a true scope and spirit of the embodiment being indicated by the following claims.

For example, according to one aspect, in a 1^{st} embodiment, a functional laminate is provided. The functional laminate may comprise an electrochromic assembly having an ion conducting interlayer film, a first electrode layer, and a second electrode layer, the first electrode layer and the second electrode layer being configured to apply an electric potential across the ion conducting interlayer film; a first layer of glass, a second layer of glass, and a gap therebetween; and a photovoltaic assembly, the photovoltaic assembly being electrically connected to the electrochromic assembly, the first layer of glass and second layer of glass being disposed between the electrochromic assembly and the photovoltaic assembly; wherein the functional laminate is optically clear.

A 2^{nd} embodiment is the 1^{st} embodiment of the functional laminate, wherein the first electrode layer and the second electrode layer are conductive films including carbon nanotubes.

A 3^{rd} embodiment is any combination of the first 2 embodiments, further including luminescent solar concentrators.

A 4^{th} embodiment is any combination of the first 3 embodiments, wherein the luminescent solar concentrators are quantum dots.

A 5^{th} embodiment is any combination of the first 4 embodiments, wherein the photovoltaic assembly includes a polymeric interlayer, the luminescent solar concentrators being disposed in the polymeric interlayer.

A 6^{th} embodiment is any combination of the first 5 embodiments, wherein the polymeric interlayer comprises ethylene co-vinyl acetate (EVA) or thermoplastic polyurethane (TPU).

A 7^{th} embodiment is any combination of the first 6 embodiments, wherein the photovoltaic assembly further includes organic photovoltaic cells.

An 8^{th} embodiment is any combination of the first 7 embodiments, wherein the organic photovoltaic cells are contained in a thin film.

A 9^{th} embodiment is any combination of the first 8 embodiments, wherein the first electrode layer and the second electrode layer are transparent.

A 10^{th} embodiment is any combination of the first 9 embodiments, wherein at least one of the first electrode layer and the second electrode layer have carbon nanotubes and another element selected from carbon, graphite, silver, and copper.

An 11^{th} embodiment is any combination of the first 10 embodiments, wherein the ion conducting interlayer film is transparent.

A 12^{th} embodiment is any combination of the first 11 embodiments, wherein the ion conducting interlayer film comprises thermoplastic polyurethane (TPU) or polymethyl methacrylate (PMMA).

A 13^{th} embodiment is any combination of the first 12 embodiments, wherein the ion conducting interlayer film includes an organic carbonate.

A 14^{th} embodiment is any combination of the first 13 embodiments, wherein the ion conducting interlayer film includes a dibenzoate or an acrylic monomer.

A 15^{th} embodiment is any combination of the first 14 embodiments, wherein the gap between the first layer of glass and second layer of glass comprises a vacuum.

A 16^{th} embodiment is any combination of the first 15 embodiments, wherein the gap between the first layer of glass and second layer of glass contains a noble gas.

A 17^{th} embodiment is any combination of the first 16 embodiments, further allowing a light transmission of about 85% to about 93%.

An 18^{th} embodiment is any combination of the first 17 embodiments, further having a haze of about 5% to less than about 1%.

According to another aspect, a 1^{st} embodiment of a self-contained window unit is provided. The self-contained window can comprise the functional laminate of the 1^{st} embodiment as described above.

A 2^{nd} embodiment is the 1^{st} embodiment of the self-contained window, further comprising a frame.

A 3^{rd} embodiment is any combination of the first 2 embodiments, further comprising a transceiver.

A 4^{th} embodiment is any combination of the first 3 embodiments, wherein the electrochromic assembly is automatically controlled.

A 5^{th} embodiment is any combination of the first 4 embodiments, further being connected to at least one of a wireless controller, mini blinds, an IoT device, and a sensor management operating system.

A 6^{th} embodiment is any combination of the first 5 embodiments, wherein the electrochromic assembly includes a carrier comprising polyethylene terephthalate (PET) or polycarbonate (PC).

A 7^{th} embodiment is any combination of the first 6 embodiments, wherein the electrochromic assembly is formed on the carrier.

An 8^{th} embodiment is any combination of the first 7 embodiments, wherein the second electrode layer is formed directly on the carrier.

A 9^{th} embodiment is any combination of the first 8 embodiments, wherein an optical interlayer is disposed on the carrier opposite the second electrode layer.

A 10^{th} embodiment is any combination of the first 9 embodiments, wherein the optical interlayer is selected from the group consisting of: a PVB layer, a solar control layer, and an optical grade EVA.

According to still another aspect, in a 1^{st} embodiment, a functional laminate is provided. The functional laminate may comprise a first layer of glass; a photovoltaic assembly disposed on the first layer of glass; a second layer of glass, a third layer of glass, and a gap therebetween; an electrochromic assembly disposed on the third layer of glass, the electrochromic assembly having an ion conducting interlayer film, a first electrode layer, and a second electrode layer, the first electrode layer and the second electrode layer being configured to apply an electric potential across the ion conducting interlayer film, the photovoltaic assembly being electrically connected to the electrochromic assembly; and a fourth layer of glass disposed on a side of the electrochromic assembly opposite the third layer of glass; wherein the functional laminate is optically clear.

A 2^{nd} embodiment is the 1^{st} embodiment of the functional laminate, further comprising a fifth layer of glass adjacent the fourth layer of glass, and a gap disposed between the fourth layer of glass and the fifth layer of glass.

A 3^{rd} embodiment is any combination of the first 2 embodiments, further comprising a layer of TPU disposed on the fifth layer of glass, and a sixth layer of glass disposed on the layer of TPU.

A 4^{th} embodiment is any combination of the first 3 embodiments, wherein the first electrode layer and the second electrode layer are conductive films including carbon nanotubes.

A 5^{th} embodiment is any combination of the first 4 embodiments, further including luminescent solar concentrators.

A 6^{th} embodiment is any combination of the first 5 embodiments, wherein the luminescent solar concentrators are quantum dots.

A 7^{th} embodiment is any combination of the first 6 embodiments, wherein the photovoltaic assembly includes a polymeric interlayer, the luminescent solar concentrators being disposed in the polymeric interlayer.

An 8^{th} embodiment is any combination of the first 7 embodiments, wherein the polymeric interlayer comprises ethylene co-vinyl acetate (EVA) or thermoplastic polyurethane (TPU).

A 9^{th} embodiment is any combination of the first 8 embodiments, f wherein the photovoltaic assembly further includes organic photovoltaic cells.

A 10^{th} embodiment is any combination of the first 11 embodiments, wherein the organic photovoltaic cells are contained in a thin film.

An 11^{th} embodiment is any combination of the first 10 embodiments, wherein the first electrode layer and the second electrode layer are transparent.

A 12^{th} embodiment is any combination of the first 11 embodiments, wherein at least one of the first electrode layer and the second electrode layer have carbon nanotubes and another element selected from carbon, graphite, silver, and copper.

A 13^{th} embodiment is any combination of the first 12 embodiments, wherein the ion conducting interlayer film is transparent.

A 14^{th} embodiment is any combination of the first 13 embodiments, wherein the ion conducting interlayer film comprises thermoplastic polyurethane (TPU) or polymethyl methacrylate (PMMA).

A 15^{th} embodiment is any combination of the first 14 embodiments, wherein the ion conducting interlayer film includes an organic carbonate.

A 16^{th} embodiment is any combination of the first 15 embodiments, wherein the ion conducting interlayer film includes a dibenzoate or an acrylic monomer.

A 17^{th} embodiment is any combination of the first 16 embodiments, wherein the gap between the second layer of glass and third layer of glass comprises a vacuum.

An 18^{th} embodiment is any combination of the first 17 embodiments, wherein the gap between the second layer of glass and third layer of glass contains a noble gas.

A 19^{th} embodiment is any combination of the first 18 embodiments, further allowing a light transmission of about 85% to about 93%.

A 20^{th} embodiment is any combination of the first 19 embodiments, further having a haze of about 5% to less than about 1%.

According to yet another aspect, in a 1^{st} embodiment, a self-contained window unit is provided. The self-contained window until can have the functional laminate of the 1^{st} embodiment as described above.

A 2^{nd} embodiment is the 1^{st} embodiment of the self-contained window unit, further comprising a frame.

A 3^{rd} embodiment is any combination of the first 2 embodiments, further comprising a transceiver.

A 4^{th} embodiment is any combination of the first 3 embodiments, wherein the electrochromic assembly is automatically controlled.

A 5^{th} embodiment is any combination of the first 4 embodiments, further being connected to at least one of a wireless controller, mini blinds, an IoT device, and a sensor management operating system.

A 6^{th} embodiment is any combination of the first 5 embodiments, wherein the electrochromic assembly includes a carrier comprising polyethylene terephthalate (PET) or polycarbonate (PC).

A 7^{th} embodiment is any combination of the first 6 embodiments, wherein the electrochromic assembly is formed on the carrier.

An 8^{th} embodiment is any combination of the first 7 embodiments, wherein the second electrode layer is formed directly on the carrier.

A 9^{th} embodiment is any combination of the first 8 embodiments, wherein an optical interlayer is disposed on the carrier opposite the second electrode layer.

A 10^{th} embodiment is any combination of the first 9 embodiments, wherein the optical interlayer is selected from the group consisting of: a PVB layer, a solar control layer, and an optical grade EVA.

it are optically clear.

What is claimed is:

1. A functional laminate, comprising:
an electrochromic assembly having an ion conducting interlayer film, a first electrode layer, and a second electrode layer, the first electrode layer and the second electrode layer being configured to apply an electric potential across the ion conducting interlayer film;
a first layer of glass, a second layer of glass, and a gap therebetween; and
a photovoltaic assembly, the photovoltaic assembly being electrically connected to the electrochromic assembly, the first layer of glass and second layer of glass being disposed between the electrochromic assembly and the photovoltaic assembly;
wherein the functional laminate is optically clear.

2. The functional laminate according to claim 1, wherein the first electrode layer and the second electrode layer are conductive films including carbon nanotubes.

3. The functional laminate according to claim 1, further including luminescent solar concentrators.

4. The functional laminate according to claim 3, wherein the luminescent solar concentrators are quantum dots.

5. The functional laminate according to claim 3, wherein the photovoltaic assembly includes a polymeric interlayer, the luminescent solar concentrators being disposed in the polymeric interlayer.

6. The functional laminate according to claim 5, wherein the polymeric interlayer comprises ethylene co-vinyl acetate (EVA) or thermoplastic polyurethane (TPU).

7. The functional laminate according to claim 1, wherein the photovoltaic assembly further includes organic photovoltaic cells.

8. The functional laminate according to claim 7, wherein the organic photovoltaic cells are contained in a thin film.

9. The functional laminate according to claim 1, wherein the first electrode layer and the second electrode layer are transparent.

10. The functional laminate according to claim 9, wherein at least one of the first electrode layer and the second electrode layer have carbon nanotubes and another element selected from carbon, graphite, silver, and copper.

11. The functional laminate according to claim 1, wherein the ion conducting interlayer film is transparent.

12. The functional laminate according to claim 1, wherein the ion conducting interlayer film comprises thermoplastic polyurethane (TPU) or polymethyl methacrylate (PMMA).

13. The functional laminate according to 12, wherein the ion conducting interlayer film includes an organic carbonate.

14. The functional laminate according to claim 12, wherein the ion conducting interlayer film includes a dibenzoate or an acrylic monomer.

15. The functional laminate according to claim 1, wherein the gap between the first layer of glass and second layer of glass comprises a vacuum.

16. The functional laminate according to claim 1, wherein the gap between the first layer of glass and second layer of glass contains a noble gas.

17. The functional laminate according to claim 1, further allowing a light transmission of about 85% to about 93%.

18. The functional laminate according to claim 1, further having a haze of about 5% to less than about 1%.

19. A self-contained window unit comprising the functional laminate according to claim 1.

20. The self-contained window unit according to claim 19, further comprising a frame.

21. The self-contained window unit according to claim 19, further comprising a transceiver.

22. The self-contained window unit according to claim 21, wherein the electrochromic assembly is automatically controlled.

23. The self-contained window unit according to claim 19, further being connected to at least one of a wireless controller, mini blinds, an IoT device, and a sensor management operating system.

24. The self-contained window unit according to claim 19, wherein the electrochromic assembly includes a carrier comprising polyethylene terephthalate (PET) or polycarbonate (PC).

25. The self-contained window unit according to claim 24, wherein the electrochromic assembly is formed on the carrier.

26. The self-contained window unit according to claim 25, wherein the second electrode layer is formed directly on the carrier.

27. The self-contained window unit according to claim 26, wherein an optical interlayer is disposed on the carrier opposite the second electrode layer.

28. The self-contained window unit according to claim 27, wherein the optical interlayer is selected from the group consisting of: a PVB layer, a solar control layer, and an optical grade EVA.
